(19) United States
(12) Patent Application Publication
(10) Pub. No.: US 2022/0102513 A1
(43) Pub. Date: Mar. 31, 2022

(54) SEMICONDUCTOR MEMORY DEVICE

(71) Applicant: SK hynix Inc., Icheon-si Gyeonggi-do (KR)

(72) Inventors: Jin Ho BIN, Icheon-si Gyeonggi-do (KR); Il Young KWON, Icheon-si Gyeonggi-do (KR); Tae Hong GWON, Icheon-si Gyeonggi-do (KR); Seok Joo KIM, Icheon-si Gyeonggi-do (KR); Su Jin NOH, Icheon-si Gyeonggi-do (KR); Young Jin NOH, Icheon-si Gyeonggi-do (KR); Jae O PARK, Icheon-si Gyeonggi-do (KR); Jin Ho OH, Icheon-si Gyeonggi-do (KR); Dong Chul YOO, Icheon-si Gyeonggi-do (KR); Jae Jin YUN, Icheon-si Gyeonggi-do (KR); Su Hyun LEE, Icheon-si Gyeonggi-do (KR); Yoo Il JEON, Icheon-si Gyeonggi-do (KR)

(73) Assignee: SK hynix Inc., Icheon-si Gyeonggi-do (KR)

(21) Appl. No.: 17/215,814

(22) Filed: Mar. 29, 2021

(30) Foreign Application Priority Data
Sep. 28, 2020 (KR) 10-2020-0125689

(51) Int. Cl. H01L 29/423; H01L 27/1157; H01L 27/11582; H01L 21/28; H01L 29/51

(52) U.S. Cl. CPC H01L 29/4234; H01L 27/1157; H01L 29/518; H01L 29/40117; H01L 29/513; H01L 27/11582

(57) ABSTRACT

A semiconductor memory device includes: a tunnel insulating layer disposed between a conductive pattern and a channel layer; a data storage layer disposed between the conductive pattern and the tunnel insulating layer, the data storage layer including a silicon nitride layer; a first blocking insulating layer disposed between the conductive pattern and the data storage layer; a second blocking insulating layer disposed between the conductive pattern and the first blocking insulating layer; and a carbon containing layer disposed at at least one position among a position between the tunnel insulating layer and the data storage layer, a position between the first blocking insulating layer and the data storage layer, a position in the tunnel insulating layer, and a position between the first blocking insulating layer and the second blocking insulating layer.

### CROSS-REFERENCE TO RELATED APPLICATION

The present application claims priority under 35 U.S.C. § 119(a) to Korean patent application number 10-2020-0125689, filed on Sep. 28, 2020, in the Korean Intellectual Property Office, the entire disclosure of which is incorporated herein by reference.

### BACKGROUND

### 1. Technical Field

The present disclosure generally relates to a semiconductor memory device, and more particularly, to a nonvolatile semiconductor memory device.

### 2. Related Art

A semiconductor memory device includes a memory cell which stores data. A memory cell of a nonvolatile memory device may retain stored data even when its supply of power is interrupted. The memory cell of the nonvolatile memory device may include a data storage layer disposed between a gate and a channel.

In order to improve the degree of integration of the nonvolatile memory device, there has been proposed a three-dimensional nonvolatile memory device including three-dimensionally arranged memory cells. In a process of manufacturing the three-dimensional nonvolatile memory device, the reliability of a data storage layer may deteriorate to some degree.

### SUMMARY

In accordance with an embodiment of the present disclosure, a semiconductor memory device includes: a stack structure including interlayer insulating layers alternately stacked with conductive patterns; a channel layer penetrating the stack structure; a tunnel insulating layer disposed between the channel layer and each of the conductive patterns; a data storage layer disposed between the tunnel insulating layer and each of the conductive patterns, the data storage layer including a silicon nitride layer; a blocking insulating layer disposed between the data storage layer and each of the conductive patterns; and a first carbon containing layer disposed between the tunnel insulating layer and the data storage layer.

In accordance with another embodiment of the present disclosure, a semiconductor memory device includes: a stack structure including interlayer insulating layers alternately stacked with conductive patterns; a channel layer penetrating the stack structure; a tunnel insulating layer disposed between the channel layer and each of the conductive patterns; a data storage layer disposed between the tunnel insulating layer and each of the conductive patterns, the data storage layer including a silicon nitride layer; a blocking insulating layer disposed between the data storage layer and each of the conductive patterns; and a carbon containing layer disposed between the data storage layer and the blocking insulating layer.

In accordance with still another embodiment of the present disclosure, a semiconductor memory device includes: a tunnel insulating layer disposed between a conductive pattern and a channel layer; a data storage layer disposed between the conductive pattern and the tunnel insulating layer, the data storage layer including a silicon nitride layer; a first blocking insulating layer disposed between the conductive pattern and the data storage layer; a second blocking insulating layer disposed between the conductive pattern and the first blocking insulating layer; and a carbon containing layer disposed at at least one position among a position between the tunnel insulating layer and the data storage layer, a position between the first blocking insulating layer and the data storage layer, a position in the tunnel insulating layer, and a position between the first blocking insulating layer and the second blocking insulating layer, wherein the data storage layer further includes at least one silicon carbon nitride (SiCN) layer, and the at least one SiCN layer isolates the silicon nitride layer into charge trap layers.

### BRIEF DESCRIPTION OF THE DRAWINGS

Illustrative embodiments will now be described hereinafter with reference to the accompanying drawings; however, other embodiments may take on different forms. Therefore, possible embodiments of the present teachings should not be construed as being limited to the specific embodiments set forth herein.

In the drawing, dimensions may be exaggerated for clarity of illustration. It will be understood that when an element is referred to as being “between” two elements, it can be the only element between the two elements, or one or more intervening elements may also be present. Like reference numerals refer to like elements throughout the drawings.

FIG. 1 is a block diagram illustrating a semiconductor memory device in accordance with an embodiment of the present disclosure.

FIG. 2 is a circuit diagram illustrating a memory cell string in accordance with an embodiment of the present disclosure.

FIGS. 3A to 3E are perspective views illustrating semiconductor memory devices in accordance with embodiments of the present disclosure.

FIGS. 4A to 4C are perspective views illustrating data storage layers in accordance with embodiments of the present disclosure.

FIG. 5 is a view illustrating positions of a carbon containing layer and an anti-oxidation layer in accordance with embodiments of the present disclosure.

FIG. 6 is a flowchart illustrating a manufacturing method of a semiconductor memory device in accordance with an embodiment of the present disclosure.

FIGS. 7A and 7B are flowcharts illustrating various embodiments of a process performed after step S11A shown in FIG. 6.

FIGS. 8 to 10 are flowcharts illustrating various embodiments of the manufacturing method of the semiconductor memory device.

FIG. 11 is a block diagram illustrating a configuration of a memory system in accordance with an embodiment of the present disclosure.

FIG. 12 is a block diagram illustrating a configuration of a computing system in accordance with an embodiment of the present disclosure.

### DETAILED DESCRIPTION

Specific structural or functional descriptions disclosed herein are merely illustrative for the purpose of describing embodiments according to the concept of the present disclosure. Embodiments can be implemented in various forms, and thus, possible embodiments should not be construed as being limited to the embodiments set forth herein.

Hereinafter, the terms ‘first’ and ‘second’ are used to distinguish one component from another component and not to indicate a number or order of components. As such, the components should not be limited by these terms.

Some embodiments are directed to a semiconductor memory device capable of improving the reliability of a data storage layer.

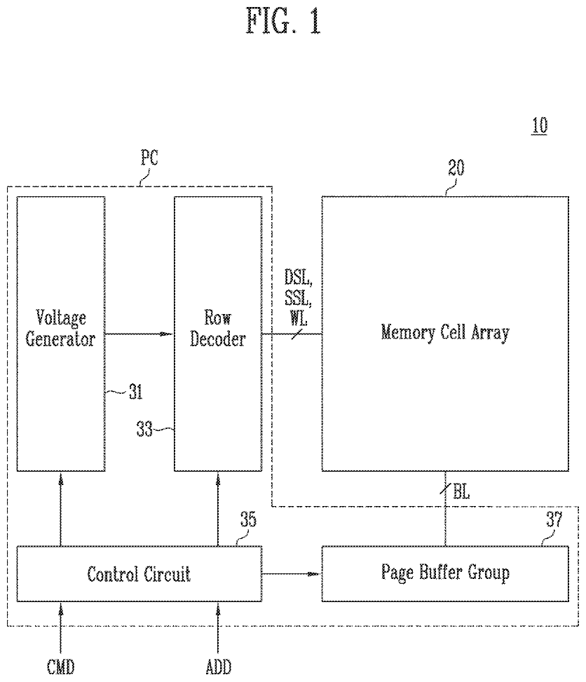

FIG. 1 is a block diagram illustrating a semiconductor memory device 10 in accordance with an embodiment of the present disclosure.

Referring to FIG. 1, the semiconductor memory device 10 includes a peripheral circuit PC and a memory cell array 20.

The peripheral circuit PC may be configured to control a program operation for storing data in the memory cell array 20, a read operation for outputting data stored in the memory cell array 20, and an erase operation for erasing data stored in the memory cell array 20.

In an embodiment, the peripheral circuit PC may include a voltage generator 31, a row decoder 33, a control circuit 35, and a page buffer group 37.

The memory cell array 20 may include a plurality of memory blocks. The memory cell array 20 may be connected to the row decoder 33 through a drain select line DSL, a source select line SSL, and word lines WL. The memory cell array 20 may be connected to the page buffer group 37 through bit lines BL.

The control circuit 35 may control the peripheral circuit PC in response to a command CMD and an address ADD.

The control circuit 35 may control the voltage generator 31 to generate various operating voltages, which are used for a program operation, a read operation, and an erase operation, under the control of the control circuit 35. The voltage generator 31 may generate various operating voltages such as a pre-erase voltage, an erase voltage, a ground voltage, a program voltage, a verify voltage, a pass voltage, and a read voltage.

The control circuit 35 may control the row decoder 33 to select a memory block. The row decoder 33 may apply operating voltages to the word lines WL connected to the selected memory block.

The page buffer group 37 may be connected to the memory cell array 20 through the bit lines BL. The control circuit 35 may control the page buffer group 37 to temporarily store data received from an input/output circuit (not shown) in a program operation. The control circuit 35 may control the page buffer group 37 to sense a voltage or current of the bit lines BL in a read operation or a verify operation. The control circuit 35 may control the page buffer group 37 to select the bit lines BL.

The memory block of the memory cell array 20 may include a plurality of memory cell strings.

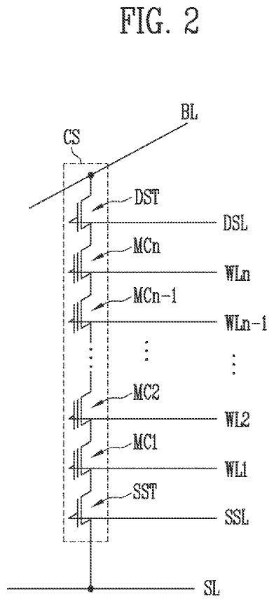

FIG. 2 is a circuit diagram illustrating a memory cell string in accordance with an embodiment of the present disclosure.

Referring to FIG. 2, the memory cell string CS may be connected to a source layer SL and a bit line BL. The memory cell string CS may include a plurality of memory cells MC1 to MCn, at least one source select transistor SST, and at least one drain select transistor DST.

The plurality of memory cells MC1 to MCn may be connected in series. Gates of the plurality of memory cells MC1 to MCn may be respectively connected to a plurality of word lines WL1 to WLn stacked to be spaced apart from each other.

The at least source select transistor SST may control electrical connection between the plurality of memory cells MC1 to MCn and the source layer SL. In an embodiment, the memory cell string CS may include one source select transistor SST disposed between the source layer SL and the plurality of memory cells MC1 to MCn. Although not shown in the drawing, in another embodiment, the memory cell string CS may include two or more source select transistors connected in series to each other between the source layer SL and the plurality of memory cells MC1 to MCn. A gate of the source select transistor SST may be connected to a source select line SSL.

The at least one drain select transistor DST may control electrical connection between the plurality of memory cells MC1 to MCn and the bit line BL. In an embodiment, the memory cell string CS may include one drain select transistor DST disposed between the bit line BL and the plurality of memory cells MC1 to MCn. Although not shown in the drawing, in another embodiment, the memory cell string CS may include two or more drain select transistors connected in series between the bit line BL and the plurality of memory cells MC1 to MCn. A gate of the drain select transistor DST may be connected to a drain select line DSL.

The word lines WL1 to WLn may be implemented with conductive patterns stacked to be spaced apart from each other by interlayer insulating layers. The memory cells MC1 to MCn may be defined at intersection portions of a channel layer penetrating conductive patterns for the word lines WL1 to WLn and the conductive patterns.

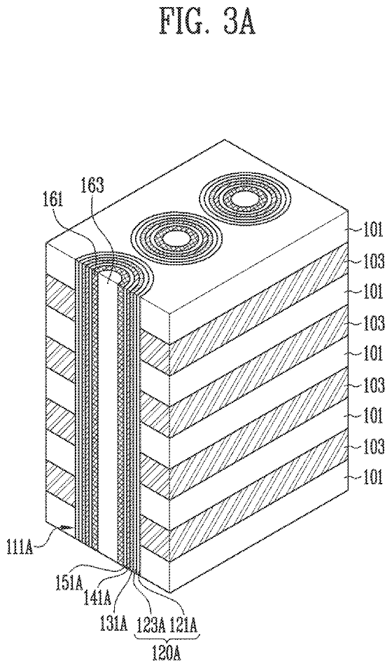

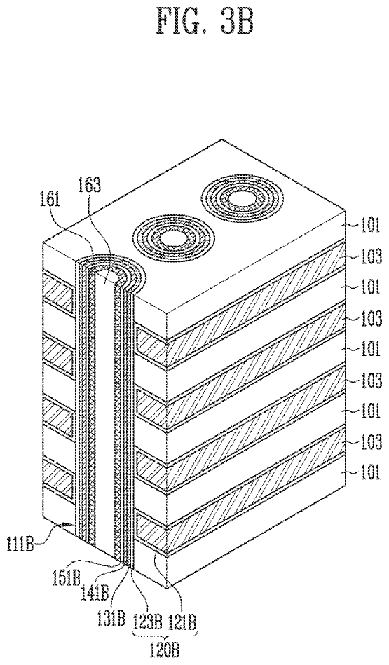

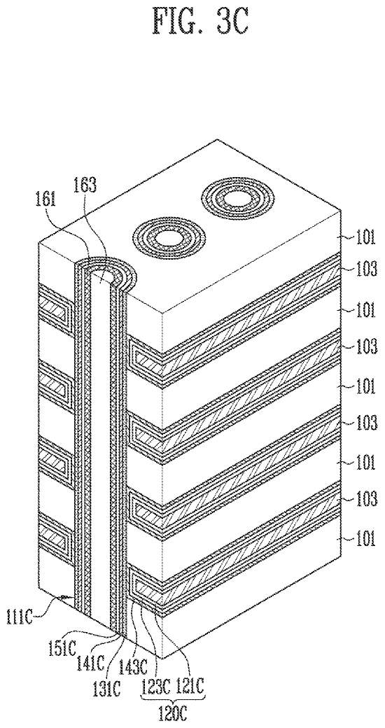

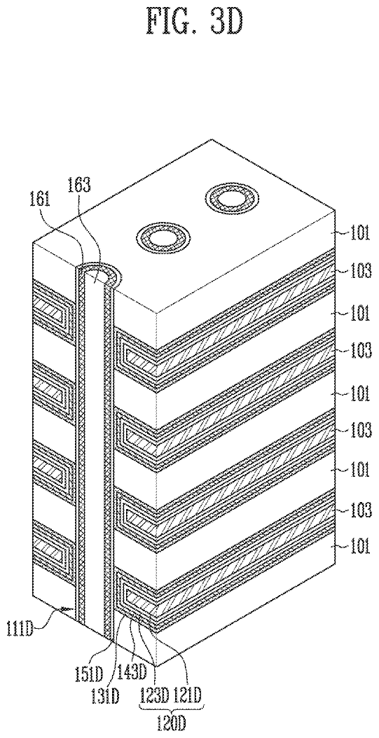

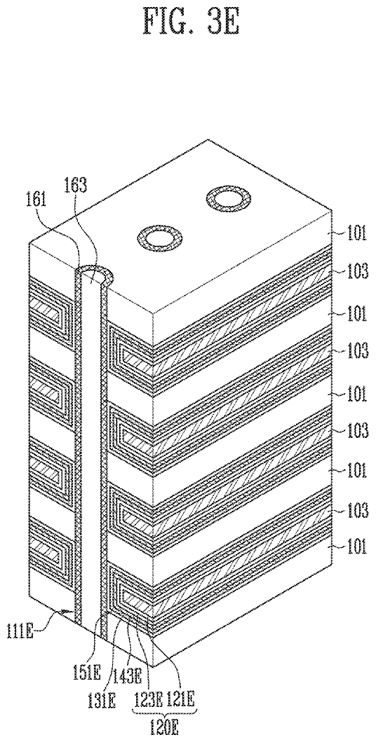

FIGS. 3A to 3E are perspective views illustrating semiconductor memory devices in accordance with embodiments of the present disclosure.

Referring to FIG. 3A to 3E, each of the semiconductor memory devices may include interlayer insulating layers 101 and conductive patterns 103, which are alternately stacked. The conductive patterns 103 may be used as the word lines WL1 to WLn described with reference to FIG. 2.

The interlayer insulating layers 101 and the conductive patterns 103 may be penetrated by a channel layer 161. The channel layer 161 may surround a sidewall of a core insulating layer 163. The core insulating layer 163 may be disposed in a central region of a hole 111A, 111B, 111C, 111D, or 111E penetrating the interlayer insulating layers 101 and the conductive patterns 103. The channel layer 161 may include a semiconductor material. In an embodiment, the channel layer 161 may include silicon.

A multi-layer may be disposed between the channel layer 161 and each of the conductive patterns 103. The multi-layer may include a tunnel insulating layer 151A, 151B, 151C, 151D, or 151E, a data storage layer 131A, 131B, 131C, 131D, or 131E, and a blocking insulating layer 120A, 120B, 120C, 120D, or 120E. Also, the multi-layer may include at least one of carbon containing layers 141A, 141B, 141C, 143C, 143D, and 143E.

The tunnel insulating layer 151A, 151B, 151C, 151D, or 151E may be disposed between and the channel layer 161 and each of the conductive patterns 103. The tunnel insulating layer 151A, 151B, 151C, 151D, or 151E may include an insulating material through which charges can tunnel. The tunnel insulating layer 151A, 151B, 151C, 151D, or 151E may include a silicon oxide layer.

The data storage layer 131A, 131B, 131C, 131D, or 131E may be disposed between the tunnel insulating layer 151A, 151B, 151C, 151D, or 151E and each of the conductive patterns 103. The data storage layer 131A, 131B, 131C, 131D, or 131E may serve as a data storage region. The data storage layer 131A, 131B, 131C, 131D, or 131E may include a silicon nitride layer in which charges can be trapped. The silicon nitride layer has an excellent data retention characteristic as compared with a floating gate, and is advantageous in integration as compared with the floating gate.

The blocking insulating layer 120A, 120B, 120C, 120D, or 120E may be disposed between the data storage layer 131A, 131B, 131C, 131D, or 131E and each of the conductive patterns 103. The blocking insulating layer 120A, 120B, 120C, 120D, or 120E may include an insulating material capable of preventing a phenomenon in which charges are introduced to the conductive patterns 103 by tunneling. In an embodiment, the blocking insulating layer 120A, 120B, 120C, 120D, or 120E may include a first blocking insulating layer 123A, 123B, 123C, 123D, or 123E and a second blocking insulating layer 121A, 121B, 121C, 121D, or 121E. The first blocking insulating layer 123A, 123B, 123C, 123D, or 123E may be disposed between the data storage layer 131A, 131B, 131C, 131D, or 131E and each of the conductive patterns 103. The second blocking insulating layer 121A, 121B, 121C, 121D, or 121E may be disposed between the first blocking insulating layer 123A, 123B, 123C, 123D, or 123E and each of the conductive patterns 103. The second blocking insulating layer 121A, 121B, 121C, 121D, or 121E may include an insulating material having a dielectric constant higher than that of the first blocking insulating layer 123A, 123B, 123C, 123D, or 123E. In an embodiment, the first blocking insulating layer 123A, 123B, 123C, 123D, or 123E may include a silicon oxide layer, and the second blocking insulating layer 121A, 121B, 121C, 121D, or 121E may include a metal oxide layer such as an aluminum oxide layer or hafnium oxide layer. Although not shown in the drawings, the second blocking insulating layer 121A, 121B, 121C, 121D, or 121E may be omitted from some embodiments.

Positions of the carbon containing layers 141A, 141B, 141C, 143C, 143D, and 143E may be designed by considering an oxidation phenomenon. The oxidation phenomenon may occur in a process of forming the tunnel insulating layer 151A, 151B, 151C, 151D, or 151E and a process of forming the blocking insulating layer 120A, 120B, 120C, 120D, or 120E. The carbon containing layers 141A, 141B, 141C, 143C, 143D, and 143E may include oxide of an anti-oxidation layer deposited to mitigate or prevent oxidation. In an embodiment, the carbon containing layers 141A, 141B, 141C, 143C, 143D, and 143E may include oxide of silicon carbon nitride (SiCN).

In an embodiment, the oxide of the silicon carbon nitride (SiCN) may include silicon oxycarbide (SiOC). In another embodiment, the oxide of the silicon carbon nitride (SiCN) may include silicon carbide (SiC) and silicon oxynitride (SiON). In still another embodiment, the oxide of the silicon carbon nitride (SiCN) may include carbon nitride (CN) and silicon dioxide (SiO₂).

The positions of the carbon containing layers 141A, 141B, 141C, 143C, 143D, and 143E may be designed by considering an order in which a process of forming the data storage layer 131A, 131B, 131C, 131D, or 131E, a process of forming the tunnel insulating layer 151A, 151B, 151C, 151D, or 151E, and a process of forming the blocking insulating layer 120A, 120B, 120C, 120D, or 120E are performed.

In an embodiment the tunnel insulating layer 151A, 151B, or 151C shown in FIGS. 3A to 3C may be formed after a process of forming the data storage layer 131A, 131B, or 131C. In order to mitigate or prevent oxidation of the data storage layer 131A, 131B, or 131C, silicon carbon nitride (SiCN) may be formed on a sidewall of the data storage layer 131A, 131B, or 131C, before the tunnel insulating layer 151A, 151B, or 151C is formed. Subsequently, the carbon containing layers 141A, 141B, and 141C may be formed by oxidizing the silicon carbon nitride (SiCN), during the process of forming the tunnel insulating layer 151A, 151B, or 151C. The oxidation of the data storage layer 131A, 131B, or 131C may be mitigated or prevented by the silicon carbon nitride (SiCN). The carbon containing layers 141A, 141B, and 141C influenced by the process of forming the tunnel insulating layer 151A, 151B, or 151C may remain between the tunnel insulating layer 151A, 151B, or 151C and the data storage layer 131A, 131B, or 131C.

The first blocking insulating layer 123A and the second blocking insulating layer 121A of the blocking insulating layer 120A shown in FIG. 3A may be formed before the data storage layer 131A is formed. The first blocking insulating layer 123B of the blocking insulating layer 120B shown in FIG. 3B may be formed before the data storage layer 131B is formed.

In an embodiment, the blocking insulating layer 120C, 120D, or 120E shown in FIGS. 3C to 3E may be formed after a process of forming the data storage layer 131C, 131D, or 131E. In order to mitigate or prevent oxidation of the data storage layer 131A, 131B, or 131C, silicon carbon nitride (SiCN) may be formed on a sidewall of the data storage layer 131C, 131D, or 131E, before the blocking insulating layer 120C, 120D, or 120E is formed. Subsequently, the carbon containing layers 143C, 143D, and 143E may be formed by oxidizing the silicon carbon nitride (SiCN, during the process of forming the blocking insulating layer 120C, 120D, or 120E. The oxidation of the data storage layer 131C, 131D, or 131E may be mitigated or prevented by the silicon carbon nitride (SiCN). The carbon containing layers 143C, 143D, and 143E influenced by the process of forming blocking insulating layer 120C, 120D, or 120E may remain between the data storage layer 131C, 131D, or 131E and the blocking insulating layer 120C, 120D, or 120E.

The tunnel insulating layer 151D or 151E shown in FIGS. 3D and 3E may be formed before the data storage layer 131D or 131E is formed.

Referring to FIG. 3A, the blocking insulating layer 120A, the data storage layer 131A, the carbon containing layer 141A, and the tunnel insulating layer 151A may be disposed in the hole 111A. In other words, each of the blocking insulating layer 120A, the data storage layer 131A, the carbon containing layer 141A, and the tunnel insulating layer 151A may penetrate a stack structure of the interlayer insulating layers 101 and the conductive patterns 103.

Referring to FIG. 3B, the first blocking insulating layer 123B, the data storage layer 131B, the carbon containing layer 141B, and the tunnel insulating layer 151B may be disposed in the hole 111B. In other words, each of the first blocking insulating layer 123B, the data storage layer 131B, the carbon containing layer 141B, and the tunnel insulating layer 151B may penetrate a stack structure of the interlayer insulating layers 101 and the conductive patterns 103. The second blocking insulating layer 121B may extend between the conductive patterns 103 and the interlayer insulating layers 101.

Referring to FIG. 3C, the semiconductor memory device may include a first carbon containing layer 141C and a second carbon containing layer 143C. The first carbon containing layer 141C may be disposed between the data storage layer 131C and the tunnel insulating layer 151C, and the second carbon containing layer 143C may be disposed between the data storage layer 131C and the blocking insulating layer 120C.

The data storage layer 131C, the first carbon containing layer 141C, and the tunnel insulating layer 151C may be disposed in the hole 111C. In other words, each of the data storage layer 131C, the first carbon containing layer 141C, and the tunnel insulating layer 151C may penetrate a stack structure of the interlayer insulating layers 101 and the conductive patterns 103. Each of the first blocking insulating layer 123C and the second blocking insulating layer 121C may extend between the conductive patterns 103 and the interlayer insulating layers 101. The second carbon containing layer 143C may extend between the blocking insulating layer 120C and each of the interlayer insulating layers 101. The blocking insulating layer 120C may be configured with the first blocking insulating layer 123C and the second blocking insulating layer 121C.

Referring to FIG. 3D, the tunnel insulating layer 151D may be disposed in the hole 111D. In other words, the tunnel insulating layer 151D may penetrate a stack structure of the interlayer insulating layers 101 and the conductive patterns 103.

Each of the first blocking insulating layer 123D and the second blocking insulating layer 121D of the blocking insulating layer 120D may extend between the conductive patterns 103 and the interlayer insulating layers 101. The carbon containing layer 143 may extend between each of the interlayer insulating layers 101 and the blocking insulating layer 120D. The data storage layer 131D may extend between each of the interlayer insulating layers 101 and the carbon containing layer 143D.

Referring to FIG. 3E, the blocking insulating layer 120E may extend between the conductive patterns 103 and the interlayer insulating layers 101. The carbon containing layer 143E may extend between the blocking insulating layer 120E and each of the interlayer insulating layers 101. The data storage layer 131E may extend between the carbon containing layer 143E and each of the interlayer insulating layers 101. The tunnel insulating layer 151E may extend between the data storage layer 131E and each of the interlayer insulating layers 101.

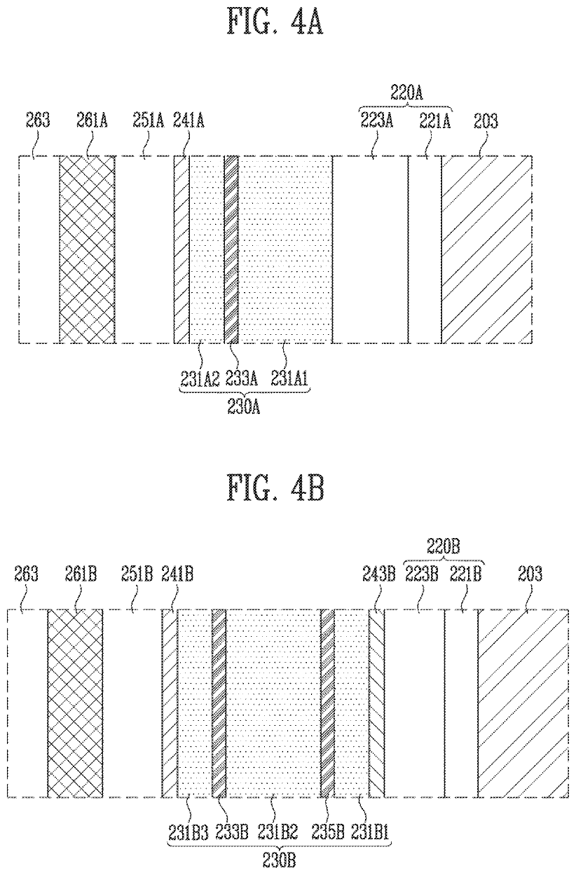

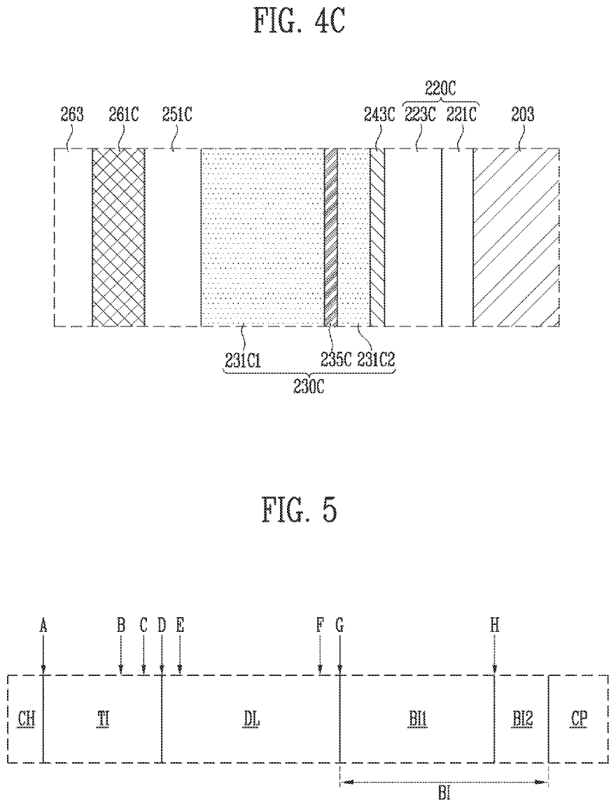

FIGS. 4A to 4C are perspective views illustrating data storage layers in accordance with embodiments of the present disclosure. FIGS. 4A to 4C are enlarged sectional views illustrating a channel layer 261A, 261B or 261C and a portion of a multi-layer, which are disposed between a conductive pattern 203 and a core insulating layer 263.

Referring to FIGS. 4A to 4C, like the embodiments exemplified in FIGS. 3A to 3E, the channel layer 261A, 261B, or 261C may surround a sidewall of the core insulating layer 263. Like the embodiments exemplified in FIGS. 3A to 3E, the conductive pattern 203 may surround a sidewall of the channel layer 261A, 261B, or 261C. The channel layer 261A, 261B, or 261C may include a semiconductor material. In an embodiment, the channel layer 261A, 261B, or 261C may include silicon.

The multi-layer may include a tunnel insulating layer 251A, 251B or 251C, a data storage layer 230A, 230B, or 230C, and a blocking insulating layer 220A, 220B, or 220C. The tunnel insulating layer 251A, 251B, or 251C, the data storage layer 230A, 230B, or 230C, and the blocking insulating layer 220A, 220B, or 220C may be disposed between the conductive pattern 203 and the channel layer 261A, 261B, or 261C.

The tunnel insulating layer 251A, 251B, or 251C may include an insulating material through which charges can tunnel. In an embodiment, the tunnel insulating layer 251A, 251B, or 251C may include a silicon oxide layer.

The blocking insulating layer 220A, 220B, or 220C may be disposed between the conductive pattern 203 and the tunnel insulating layer 251A, 251B, or 251C. The blocking insulating layer 220A, 220B, or 220C may include a first blocking insulating layer 223A, 223B, or 223C and a second blocking insulating layer 221A, 221B, or 221C. The first blocking insulating layer 223A, 223B, or 223C may include a silicon oxide layer, and the second blocking insulating layer 221A, 221B, or 221C may include a metal oxide layer such as an aluminum oxide layer or a hafnium oxide layer. Although not shown in the drawings, the second blocking insulating layer 221A, 221B, or 221C may be omitted.

The data storage layer 230A, 230B, or 230C may be disposed between the tunnel insulating layer 251A, 251B, or 251C and the blocking insulating layer 220A, 220B, or 220C. The data storage layer 230A, 230B, or 230C may be serve as a data storage region. The data storage layer 230A, 230B, or 230C may include charge trap layers isolated from each other by an anti-oxidation layer. A position of the anti-oxidation layer may be designed by considering an order in which a process of forming the data storage layer 230A, 230B, or 230C, a process of forming the tunnel insulating layer 251A, 251B, or 251C, and a process of forming the blocking insulating layer 220A, 220B, or 220C are performed.

Referring to FIG. 4A, the data storage layer 230A may be formed on a sidewall of the first blocking insulating layer 223A. The tunnel insulating layer 251A may be formed on a sidewall of the data storage layer 230A, after the data storage layer 230A is formed. The data storage layer 230A may include an anti-oxidation layer 233A, a first charge trap layer 231A1 and a second charge trap layer 231A2. The first charge trap layer 231A1 and the second charge trap layer 231A2 may be isolated from each other by the anti-oxidation layer 233A. The first charge trap layer 231A1 may be disposed between the blocking insulating layer 220A and the anti-oxidation layer 233A, and the second charge trap layer 231A2 may be disposed between the anti-oxidation layer 233A and the tunnel insulating layer 251A.

The anti-oxidation layer 233A may be disposed between the first charge trap layer 231A1 and the second charge trap layer 231A2, and may be disposed closer to the tunnel insulating layer 251A than the blocking insulating layer 220A. The first charge trap layer 231A1, the anti-oxidation layer 233A, and the second charge trap layer 231A2 may be sequentially formed. The anti-oxidation layer 233A may mitigate or prevent the first charge trap layer 231A from being oxidized, during a process of forming the tunnel insulating layer 251A.

The multi-layer may further include a carbon containing layer 241A, as described with reference to FIGS. 3A and 3B. The carbon containing layer 241A may be disposed between the tunnel insulating layer 251A and the data storage layer 230A.

Referring to FIG. 4B, the tunnel insulating layer 251B may be formed on a first sidewall of the data storage layer 230B, after the data storage layer 230B is formed. In addition, the blocking insulating layer 220B may be formed on a second sidewall of the data storage layer 230B, which faces in a direction opposite to that of the first sidewall. The data storage layer 230B may include a first anti-oxidation layer 235B, a second anti-oxidation layer 233B, a first charge trap layer 231B1, a second charge trap layer 231B2, and a third charge trap layer 231B3. The first charge trap layer 231B1, the second charge trap layer 231B2, and the third charge trap layer 231B3 may be isolated from each other by the first anti-oxidation layer 235B and the second anti-oxidation layer 233B.

The first anti-oxidation layer 235B may be disposed between the blocking insulating layer 220B and the tunnel insulating layer 251B, and the second anti-oxidation layer 233B may be disposed between the first anti-oxidation layer 235B and the tunnel insulating layer 251B. The first charge trap layer 231B1 may be disposed between the blocking insulating layer 220B and the first anti-oxidation layer 235B, the second charge trap layer 231B2 may be disposed between the first anti-oxidation layer 235B and the second anti-oxidation layer 233B, and the third charge trap layer 231B3 may be disposed between the second anti-oxidation layer 233B and the tunnel insulating layer 251B. The first charge trap layer 231B1, the first anti-oxidation layer 235B, the second charge trap layer 231B2, the second anti-oxidation layer 233B, and the third charge trap layer 231B3 may be sequentially formed.

The first anti-oxidation layer 235B may be disposed between the first charge trap layer 231B1 and the second charge trap layer 231B2, and may be disposed closer to the blocking insulating layer 220B than the tunnel insulating layer 251B. The first anti-oxidation layer 235B may mitigate or prevent the second charge trap layer 231B2 from being oxidized, during a process of forming the blocking insulating layer 220B.

The second anti-oxidation layer 233B may be disposed between the second charge trap layer 231B2 and the third charge trap layer 231B3, and may be disposed closer to the tunnel insulating layer 251B than the blocking insulating layer 220B. The second anti-oxidation layer 233B may mitigate or prevent the second charge trap layer 231B2 from being oxidized, during a process of forming the tunnel insulating layer 251B.

The multi-layer may further include a first carbon containing layer 241B and a second carbon containing layer 243B, as described with reference to FIGS. 3C and 3D. The first carbon containing layer 241B may be disposed between the tunnel insulating layer 251B and the data storage layer 230B. The second carbon containing layer 243B may be disposed between the data storage layer 230B and the blocking insulating layer 220B.

Referring to FIG. 4C, the data storage layer 230C may be formed on a sidewall of the tunnel insulating layer 251C, after the tunnel insulating layer 251C is formed. The blocking insulating layer 220C may be formed on a sidewall of the data storage layer 230C, after the data storage layer 230C is formed. The data storage layer 230C may include an anti-oxidation layer 235C, a first charge trap layer 231C1, and a second charge trap layer 231C2. The first charge trap layer 231C1 and the second charge trap layer 231C2 may be isolated from each other by the anti-oxidation layer 235C. The first charge trap layer 231C1 may be disposed between the tunnel insulating layer 251C and the anti-oxidation layer 235C, and the second charge trap layer 231C2 may be disposed between the anti-oxidation layer 235C and the blocking insulating layer 220C. The first charge trap layer 231C1, the anti-oxidation layer 235C, and the second charge trap layer 231C2 may be sequentially formed.

The anti-oxidation layer 235C may be disposed between the first charge trap layer 231C1 and the second charge trap layer 231C2, and may be disposed closer to the blocking insulating layer 220C than the tunnel insulating layer 251C. The anti-oxidation layer 235C may mitigate or prevent the first charge trap layer 231C1 from being oxidized, during a process of forming the blocking insulating layer 220C.

The multi-layer may include a carbon containing layer 243C, as described with reference to FIG. 3E. The carbon containing layer 243C may be disposed between the data storage layer 230C and the blocking insulating layer 220C.

The anti-oxidation layers 233A, 233B, 235B, and 235C shown in FIGS. 4A to 4C may include carbon. In an embodiment, the anti-oxidation layers 233A, 233B, 235B, and 235C may include silicon carbon nitride (SiCN).

The carbon containing layers 241A, 241B, 243B, and 243C shown in FIGS. 4A to 4C may include oxide of the silicon carbon nitride (SiCN), as described with reference to FIGS. 3A to 3E.

Embodiments of the present disclosure are not limited to the above-described embodiments, and positions of the carbon containing layer and the anti-oxidation layer, which are used to mitigate or prevent oxidation of the data storage layer, may be variously designed.

FIG. 5 is a view illustrating positions of a carbon containing layer and an anti-oxidation layer in accordance with embodiments of the present disclosure.

Referring to FIG. 5, a semiconductor memory device may include a channel layer CH, a conductive pattern CP, a tunnel insulating layer TI between the channel layer CH and the conductive pattern CP, a data storage layer DL between the tunnel insulating layer TI and the conductive pattern CP, and a blocking insulating layer BI between the data storage layer DL and the conductive pattern CP. The blocking insulating layer BI may include a first blocking insulating layer BI1 between the data storage layer DL and the conductive pattern CP and a second blocking insulating layer BI2 between the first blocking insulating layer BI1 and the conductive pattern CP. The tunnel insulating layer TI may include a silicon oxide layer. The data storage layer DL may include a silicon nitride layer in which charges can be trapped. The first blocking insulating layer BI1 may include a silicon oxide layer, and the second blocking insulating layer BI2 may include a metal oxide layer such as an aluminum oxide layer or a hafnium oxide layer.

A carbon containing layer made of oxide of silicon carbon nitride (SiCN) may be disposed at at least one position among position A between the channel layer CH and the tunnel insulating layer TI, the inside of the tunnel insulating layer TI, position D between the tunnel insulating layer TI and the data storage layer DL, position G between the data storage layer DL and the blocking insulating layer BI, and position H between the first blocking insulating layer BI1 and the second blocking insulating layer BI2. The carbon containing layer at the inside of the tunnel insulating layer TI may be disposed at at least one of positions B and C more adjacent to the data storage layer DL than the channel layer CH.

The oxide of the silicon carbon nitride (SiCN) may include silicon oxycarbide (SiOC), include silicon carbide (SiC) and silicon oxynitride (SiON), or include carbon nitride (CN) and silicon dioxide (SiO₂), as described with reference to FIGS. 3A to 3E.

An anti-oxidation layer containing carbon may be disposed at the inside of the data storage layer DL, and be disposed at at least one of position E adjacent to the data storage layer DL and position F adjacent to the blocking insulating layer BI. The anti-oxidation layer may include silicon carbon nitride (SiCN) as described with reference to FIGS. 4A to 4C.

A thickness of the anti-oxidation layer may be defined in a direction in which the tunnel insulating layer TI, the data storage layer DL, and the blocking insulating layer BI are arranged. A thickness of the anti-oxidation layer disposed at the positions E and F may be limited. In an embodiment, the anti-oxidation layer disposed at the position E or F may have a thickness of 5 Å to 15 Å.

The anti-oxidation layer disposed at the position F and the carbon containing layer disposed at the position G may mitigate or prevent a phenomenon in which nitrogen is diffused into the blocking insulating layer BI from the data storage layer DL including silicon nitride.

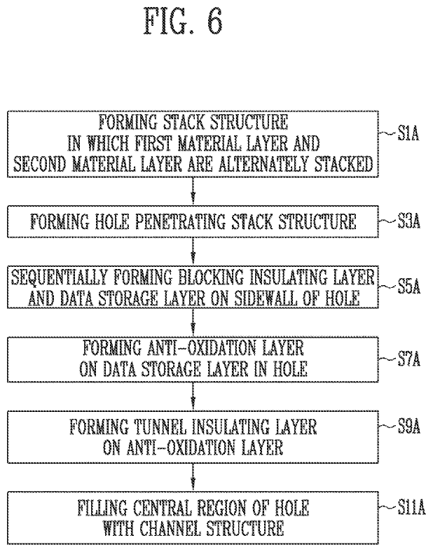

FIG. 6 is a flowchart illustrating a manufacturing method of a semiconductor memory device in accordance with an embodiment of the present disclosure.

Referring to FIG. 6, step S1A of forming a stack structure in which a first material layer and a second material layer are alternately stacked may be performed. For some embodiments, the alternately stacked first material layer and second material layer represent alternately stacked first material layers and second material layers. In an embodiment, the first material layer may include an insulating material for the interlayer insulating layers 101 shown in FIG. 3A or 3B, and the second material layer may include a sacrificial material having an etch selectivity with respect to the first material layer. In an embodiment, the sacrificial material may include a nitride layer. In another embodiment, the first material layer may include an insulating material for the interlayer insulating layers 101 shown in FIG. 3A, and the second material layer may include a conductive material for the conductive patterns 103 shown in FIG. 3A.

After the step S1A, step S3A of forming a hole penetrating the stack structure may be performed. Subsequently, step S5A of sequentially forming a blocking insulating layer and a data storage layer on a sidewall of the hole may be performed. In an embodiment, as shown in FIG. 3A, each of the first blocking insulating layer 123A, the second blocking insulating layer 121A, and the data storage layer 131A may extend along the sidewall of the hole 111A. In another embodiment, as shown in FIG. 3B, each of the first blocking insulating layer 123B and the data storage layer 131B may extend along a sidewall of the hole 111B.

Subsequently, step S7A of forming an anti-oxidation layer on the data storage layer in the hole may be performed. The anti-oxide layer may contain carbon. In an embodiment, the anti-oxidation layer may include silicon carbon nitride (SiCN).

After the anti-oxidation layer is formed, step S9A of forming a tunnel insulating layer on the anti-oxidation layer may be performed. While the step S9A is being performed, the anti-oxidation layer may be oxidized, but oxidation of the data storage layer may be suppressed by the anti-oxidation layer. Through the step S9A, as shown in FIG. 3A or 3B, the carbon containing layer 141A or 141B may be formed, and the tunnel insulating layer 151A or 151B may be formed on the carbon containing layer 141A or 141B.

Subsequently, step S11A of filling a central region of the hole with a channel structure may be performed. The channel structure may include the channel layer 161 and the core insulating layer 163 as shown in FIG. 3A or 3B.

In another embodiment, the above-described step S5A may include step of forming a silicon nitride layer constituting a charge trap layer and step of forming silicon carbon nitride (SiCN) constituting the anti-oxidation layer. Charge trap layers isolated by the anti-oxidation layer may be formed. The charge trap layers may include the data storage layer as described with reference to FIGS. 4A, 4B, and 5.

In another embodiment, in the above-described step S9A, the step of forming a silicon oxide layer and step of forming an anti-oxidation layer may be repeated. The anti-oxidation layer is oxidized while the silicon oxide layer is being formed, so that the carbon containing layer is formed. Accordingly, the carbon containing layer may remain in the tunnel insulating layer as described with reference to FIG. 5.

In another embodiment, the step S11A may include a step of forming an anti-oxidation layer on a sidewall of the tunnel insulating layer, before a channel layer is formed. The anti-oxidation layer may be oxidized by oxygen in the tunnel insulating layer, and thus the carbon containing layer is formed. Accordingly, the carbon containing layer may remain between the tunnel insulating layer and the channel layer as described with reference to FIG. 5.

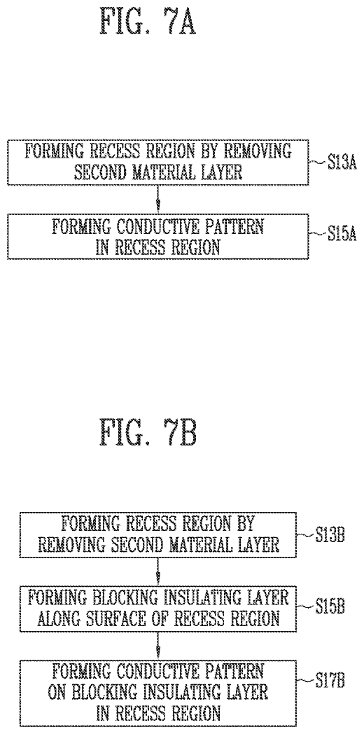

FIGS. 7A and 7B are flowcharts illustrating various embodiments of a process performed after the step S11A shown in FIG. 6. FIGS. 7A and 7B illustrate various embodiments of a process performed after the step S11A, when the second material layer, which is formed in the step S1A shown in FIG. 6, is formed of a sacrificial material.

Referring to FIG. 7A, after the step S11A shown in FIG. 6, step S13A of forming a recess region may be performed by selectively removing the second material layer.

Subsequently, step S15A of forming the conductive patterns 103 as shown in FIG. 3A in the recess region may be performed.

Referring to FIG. 7B, after the step S11A shown in FIG. 6, step S13B of forming a recess region may be performed by selectively removing the second material layer.

Subsequently, step S15B of forming a blocking insulating layer along a surface of the recess region may be performed. Through the step S15B, the second blocking insulating layer 121B may be formed as shown in FIG. 3B.

Subsequently, step S17B of forming a conductive pattern on the blocking insulating layer in the recess region may be performed. Through the step S17B, the conductive pattern 103 may be formed on the second blocking layer 121B as shown in FIG. 3B.

In another embodiment, before the step S15B, a step of forming an anti-oxidation layer may be further included. The anti-oxidation layer may be oxidized while the step S15B is being performed, and thus a carbon containing layer may be formed. Accordingly, as described with reference to FIG. 5, the carbon containing layer may remain between the first blocking insulating layer and the second blocking insulating layer as described with reference to FIG. 5.

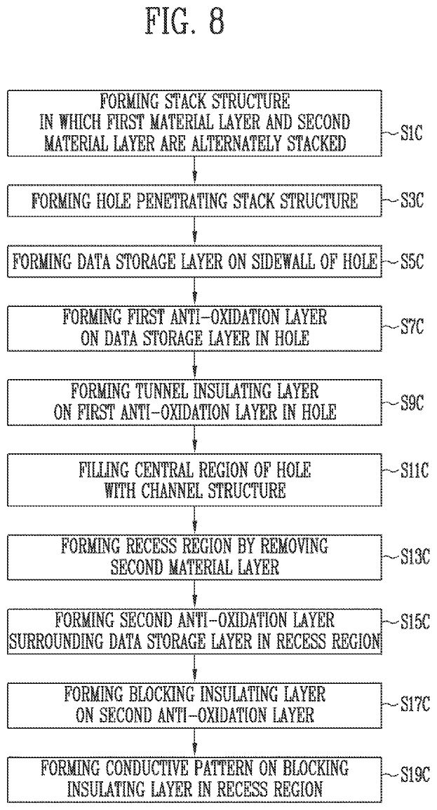

FIGS. 8 to 10 are flowcharts illustrating various embodiments of the manufacturing method of the semiconductor memory device.

Referring to FIGS. 8 to 10, step S1C, S1D or S1E of forming a stack structure in which a first material layer and a second material layer are alternately stacked may be performed. For some embodiments, the alternately stacked first material layer and second material layer represent alternately stacked first material layers and second material layers. In an embodiment, the first material layer may include an insulating material for the interlayer insulating layers 101 shown in FIG. 3C, 3D or 3E, and the second material layer may include a sacrificial material having an etch selectivity with respect to the first material layer. In an embodiment, the first material layer may include an oxide layer, and the second material layer may include a nitride layer.

Subsequently, step S3C, S3D, or S3E of forming a hole penetrating the stack structure may be performed.

Subsequent processes may be various in some embodiments.

Referring FIG. 8, after the step S3C, step S5C of forming a data storage layer on a sidewall of the hole may be performed. In an embodiment, as shown in FIG. 3C, the data storage layer 131C may extend along a sidewall of the hole 111C.

Subsequently, step S7C of forming a first anti-oxidation layer on the data storage layer in the hole may be performed. The first anti-oxidation layer may contain carbon. In an embodiment, the first anti-oxidation layer may include silicon carbon nitride (SiCN).

After the first anti-oxidation layer is formed, step S9C of forming a tunnel insulating layer on the first anti-oxidation layer may be performed. While the step S9C is being performed, the first anti-oxidation layer may be oxidized, but oxidation of the data storage layer may be suppressed by the first anti-oxidation layer. Through the step S9C, as shown in FIG. 3C, the first carbon containing layer 141C may be formed, and the tunnel insulating layer 151C may be formed on the first carbon containing layer 141C.

Subsequently, step S11C of filling a central region of the hole with a channel structure may be performed. The channel structure may include the channel layer 161 and the core insulating layer 163 as shown in FIG. 3C.

Subsequently, step S13C of forming a recess region may be performed by selectively removing the second material layer. Subsequently, step S15C of forming a second anti-oxidation layer may be performed. The second anti-oxidation layer may surround the data storage layer in the recess region. The second anti-oxidation layer may extend along a surface of the recess region. The second anti-oxidation layer may contain carbon. In an embodiment, the second anti-oxidation layer may include silicon carbon nitride (SiCN).

After the second anti-oxidation layer is formed, step S17C of forming a blocking insulating layer on the second anti-oxidation layer may be performed. While the step S17C is being performed, the second anti-oxidation layer may be oxidized, but oxidation of the data storage layer may be suppressed by the second anti-oxidation layer. Through the step S17C, as shown in FIG. 3C, the second carbon containing layer 143C may be formed, and the blocking insulating layer 120C may be formed on the second carbon containing layer 143C.

Subsequently, step S19C of forming a conductive pattern on the blocking insulating layer in the recess region may be performed. Through the step S19C, the conductive pattern 103 may be formed on the blocking insulating layer 120C as shown in FIG. 3C.

In another embodiment, the above-described step S5C may include a step of forming a silicon nitride layer constituting a charge trap layer and step of forming silicon carbon nitride (SiCN) constituting the anti-oxidation layer. Charge trap layers isolated by the anti-oxidation layer may be formed. The charge trap layers may include the data storage layer as described with reference to FIGS. 4B, and 5.

In another embodiment, in the above-described step S9C, the step of forming a silicon oxide layer and step of forming an anti-oxidation layer may be repeated. The anti-oxidation layer is oxidized while the silicon oxide layer is being formed, so that the carbon containing layer is formed. Accordingly, the carbon containing layer may remain in the tunnel insulating layer as described with reference to FIG. 5.

In another embodiment, the step S11C may include step of forming an anti-oxidation layer on a sidewall of the tunnel insulating layer, before a channel layer is formed. The anti-oxidation layer may be oxidized by oxygen in the tunnel insulating layer, and thus the carbon containing layer may be formed. Accordingly, the carbon containing layer may remain between the tunnel insulating layer and the channel layer as described with reference to FIG. 5.

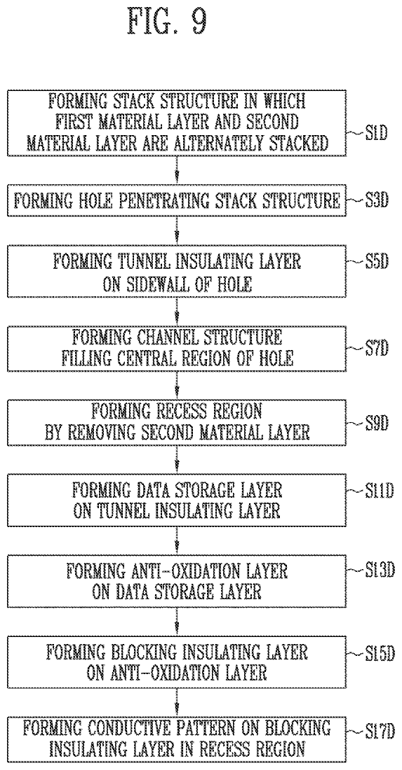

Referring to FIG. 9, after the step S3D, step S5D of forming a tunnel insulating layer on a sidewall of the hole may be performed. In an embodiment, as shown in FIG. 3D, the tunnel insulating layer 151D may extend along a sidewall of the hole 111D.

In another embodiment, the step S5D may include a process of forming a carbon containing layer in the tunnel insulating layer, and accordingly, the tunnel insulating layer including the carbon containing layer may be provided as described with reference to FIG. 5.

Subsequently, step S7D of filling a central region of the hole with a channel structure may be performed. The channel structure may include the channel layer 161 and the core insulating layer 163 as shown in FIG. 3D.

In another embodiment, the step S7D may include step of forming anti-oxidation layer on a sidewall of the tunnel insulating layer. The anti-oxidation layer may be oxidized by oxygen in the tunnel insulating layer, and thus the carbon containing layer may be formed. Accordingly, the carbon containing layer may remain between the tunnel insulating layer and the channel layer as described with reference to FIG. 5.

Subsequently, step S9D of forming a recess region may be performed by selectively removing the second material layer. Subsequently, step S11D of forming a data storage layer on the tunnel insulating layer may be performed. The data storage layer may extend along a surface of the recess region. Accordingly, as shown in FIG. 3D, the data storage layer 131D may extend along top and bottom surfaces of the interlayer insulating layers 101 formed with the first material layer.

In another embodiment, the step S9D may include step of forming a silicon nitride layer constituting a charge trap layer and step of forming silicon carbon nitride (SiCN) constituting the anti-oxidation layer. Charge trap layers isolated by the anti-oxidation layer may be formed. The charge trap layers may include the data storage layer as described with reference to FIGS. 4B, 4C, and 5.

Subsequently, step S13D of forming an anti-oxidation layer on the data storage layer may be performed. The anti-oxidation layer may contain carbon. In an embodiment, the anti-oxidation layer may include silicon carbon nitride (SiCN).

Step S15D of forming a blocking insulating layer on the anti-oxidation layer formed through the step S13D may be performed. While the step S15D is being performed, the anti-oxidation layer formed through the step S13D may be oxidized, but oxidation of the data storage layer may be suppressed by the anti-oxidation layer formed through the step S13D. Through the S15D, as shown in FIG. 3D, the carbon containing layer 143D may be formed, and the blocking insulating layer 120D may be formed on the carbon containing layer 143D.

In another embodiment, the step S15D may include a step of forming a first blocking insulating layer, a step of forming an anti-oxidation layer, and a step of forming a second blocking insulating layer. The anti-oxidation layer may be oxidized while the second blocking insulating layer is being formed, and thus the carbon containing layer may be formed. Accordingly, the carbon containing layer may remain between the first blocking insulating layer and the second blocking insulating layer as described with reference to FIG. 5.

After the step S15D, step S17D of forming a conductive pattern on the blocking insulating layer in the recess region may be performed. Through the step S17D, the conductive pattern 103 may be formed on the blocking insulating layer 120D as shown in FIG. 3D.

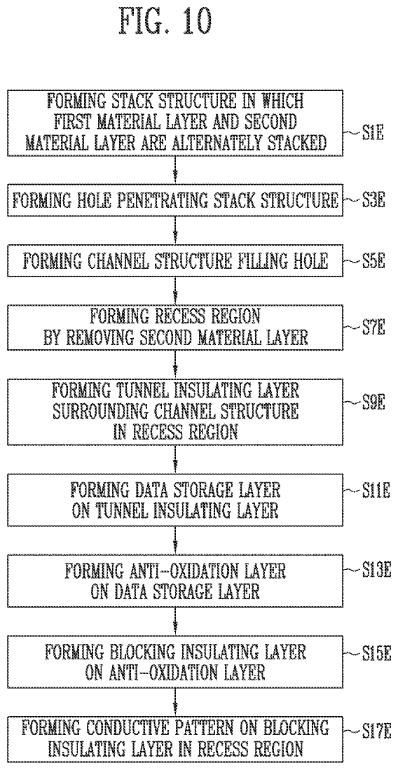

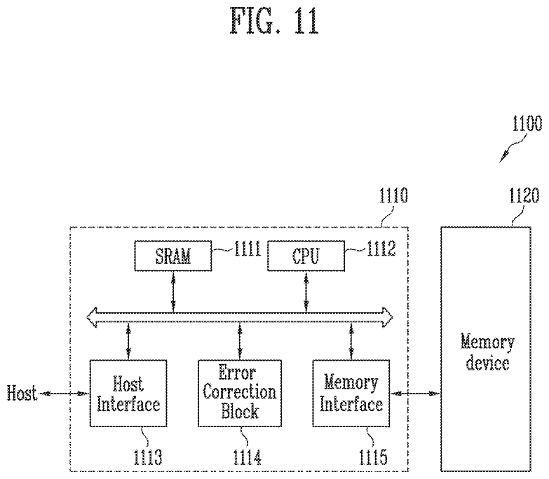

Referring to FIG. 10, after the step S3E, step S5E of filling a channel structure in the hole may be performed. The channel structure may include the channel layer 161 and the core insulating layer 163 as shown in FIG. 3E.

Subsequently, step S7E of forming a recess region may be performed by selectively removing the second material layer. Subsequently, step S9E of forming a tunnel insulating layer surrounding the channel structure in the recess region may be performed. The tunnel insulating layer may extend along a surface of the recess region. Accordingly, as shown in FIG. 3E, the tunnel insulating layer 151E may extend along top and bottom surfaces of the interlayer insulating layers 101 formed with the first material layer.

Subsequently, step S11E of forming a data storage layer on the tunnel insulating layer and step S13E of forming an anti-oxidation layer on the data storage layer may be sequentially performed. The anti-oxidation layer may contain carbon. In an embodiment, the anti-oxidation layer may include silicon carbon nitride (SiCN).

After the anti-oxidation layer is formed, step S15E of forming a blocking insulating layer on the anti-oxidation layer may be performed. While the step S15E is being performed, the anti-oxidation layer may be oxidized, but oxidation of the data storage layer may be suppressed by the anti-oxidation layer. Through the step S15E, as shown in FIG. 3E, the carbon containing layer 143E may be formed, and the blocking insulating layer 120E may be formed on the carbon containing layer 143E.

Subsequently, step S17E of forming a conductive pattern on the blocking insulating layer in the recess region may be performed. Through the step S17E, the conductive pattern 103 may be formed on the blocking insulating layer 120E as shown in FIG. 3E.

In accordance with the above-described embodiments, the oxidation of the data storage layer may be mitigated or prevented by the anti-oxidation layer containing carbon. Accordingly, the reliability of the data storage layer may be improved.

FIG. 11 is a block diagram illustrating a configuration of a memory system 1100 in accordance with an embodiment of the present disclosure.

Referring to FIG. 11, the memory system 1100 includes a memory device 1120 and a memory controller 1110.

The memory device 1120 may include a tunnel insulating layer disposed between a conductive pattern and a channel layer, a data storage layer disposed between the conductive pattern and the tunnel insulating layer, a blocking insulating layer disposed between the conductive pattern and the data storage layer, and a carbon containing layer between the conductive pattern and the channel layer. The carbon containing layer may be disposed at at least one position among a position between the tunnel insulating layer and the data storage layer, a position between a first blocking insulating layer and the data storage layer, a position in the tunnel insulating layer, and a position between the first blocking insulating layer and a second blocking insulating layer.

The memory device 1120 may be a multi-chip package configured with a plurality of flash memory chips.

The memory controller 1110 controls the memory device 1120, and may include Static Random Access Memory (SRAM) 1111, a Central Processing Unit (CPU) 1112, a host interface 1113, an error correction block 1114, and a memory interface 1115. The SRAM 1111 is used as an operation memory of the CPU 1112, the CPU 1112 performs overall control operations for data exchange of the memory controller 1110, and the host interface 1113 includes a data exchange protocol for a host connected with the memory system 1100. The error correction block 1114 detects and corrects an error included in a data read from the memory device 1120. The memory interface 1115 interfaces with the memory device 1120. The memory controller 1110 may further include Read Only Memory (ROM) for storing code data for interfacing with the host, and the like.

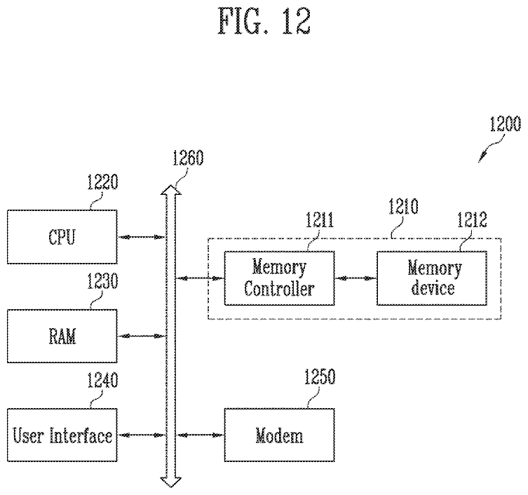

FIG. 12 is a block diagram illustrating a configuration of a computing system 1200 in accordance with an embodiment of the present disclosure.

Referring to FIG. 12, the computing system 1200 may include a CPU 1220, random access memory (RAM) 1230, a user interface 1240, a modem 1250, and a memory system 1210, which are electrically connected to a system bus 1260. The computing system 1200 may be a mobile device.

The memory system 1210 may be configured with a memory device 1212 and a memory controller 1211. The memory device 1212 may include a tunnel insulating layer disposed between a conductive pattern and a channel layer, a data storage layer disposed between the conductive pattern and the tunnel insulating layer, a blocking insulating layer disposed between the conductive pattern and the data storage layer, and a carbon containing layer between the conductive pattern and the channel layer. The carbon containing layer may be disposed at at least one position among a position between the tunnel insulating layer and the data storage layer, a position between a first blocking insulating layer and the data storage layer, a position in the tunnel insulating layer, and a position between the first blocking insulating layer and a second blocking insulating layer.

In accordance with the present disclosure, a phenomenon in which a data storage layer is oxidized may be mitigated or prevented by using a layer containing carbon, and thus the reliability of the data storage layer may be improved.

What is claimed is:

1. A semiconductor memory device comprising:
a stack structure including interlayer insulating layers alternately stacked with conductive patterns;
a channel layer penetrating the stack structure;
a tunnel insulating layer disposed between the channel layer and each of the conductive patterns;
a data storage layer disposed between the tunnel insulating layer and each of the conductive patterns, the data storage layer including a silicon nitride layer;
a blocking insulating layer disposed between the data storage layer and each of the conductive patterns; and
a first carbon containing layer disposed between the tunnel insulating layer and the data storage layer.

2. The semiconductor memory device of claim 1, wherein the first carbon containing layer includes silicon oxycarbide (SiOC).

3. The semiconductor memory device of claim 1, wherein the first carbon containing layer includes silicon carbide (SiC) and silicon oxynitride (SiON).

4. The semiconductor memory device of claim 1, wherein the first carbon containing layer includes carbon nitride (CN) and silicon dioxide (SiO₂).

5. The semiconductor memory device of claim 1, further comprising a second carbon containing layer disposed between the data storage layer and the blocking insulating layer.

6. The semiconductor memory device of claim 5, wherein the second carbon containing layer includes silicon oxycarbide (SiOC).

7. The semiconductor memory device of claim 5, wherein the second carbon containing layer includes silicon carbide (SiC) and silicon oxynitride (SiON).

8. The semiconductor memory device of claim 5, wherein the second carbon containing layer includes carbon nitride (CN) and silicon dioxide (SiO₂).

9. The semiconductor memory device of claim 1, wherein the blocking insulating layer includes:
a first blocking insulating layer disposed between the data storage layer and each of the conductive patterns; and
a second blocking insulating layer disposed between the first blocking insulating layer and each of the conductive patterns, the second blocking insulating layer having a dielectric constant higher than a dielectric constant of the first blocking insulating layer.

10. The semiconductor memory device of claim 9, further comprising a second carbon containing layer disposed between the first blocking insulating layer and the second blocking insulating layer.

11. The semiconductor memory device of claim 1, wherein the data storage layer further includes at least one silicon carbon nitride (SiCN) layer which isolates the silicon nitride layer into charge trap layers.

12. The semiconductor memory device of claim 1, further comprising a second carbon containing layer formed in the tunnel insulating layer.

13. A semiconductor memory device comprising:
a stack structure including interlayer insulating layers alternately stacked with conductive patterns;
a channel layer penetrating the stack structure;
a tunnel insulating layer disposed between the channel layer and each of the conductive patterns;
a data storage layer disposed between the tunnel insulating layer and each of the conductive patterns, the data storage layer including a silicon nitride layer;
a blocking insulating layer disposed between the data storage layer and each of the conductive patterns; and
a carbon containing layer disposed between the data storage layer and the blocking insulating layer.

14. The semiconductor memory device of claim 13, wherein the carbon containing layer includes silicon oxycarbide (SiOC).

15. The semiconductor memory device of claim 13, wherein the carbon containing layer includes silicon carbide (SiC) and silicon oxynitride (SiON).

16. The semiconductor memory device of claim 13, wherein the carbon containing layer includes carbon nitride (CN) and silicon dioxide (SiO₂).

17. A semiconductor memory device comprising:
a tunnel insulating layer disposed between a conductive pattern and a channel layer;
a data storage layer disposed between the conductive pattern and the tunnel insulating layer, the data storage layer including a silicon nitride layer;
a first blocking insulating layer disposed between the conductive pattern and the data storage layer;
a second blocking insulating layer disposed between the conductive pattern and the first blocking insulating layer; and
a carbon containing layer disposed at at least one position among a position between the tunnel insulating layer and the data storage layer, a position between the first blocking insulating layer and the data storage layer, a position in the tunnel insulating layer, and a position between the first blocking insulating layer and the second blocking insulating layer,
wherein the data storage layer further includes at least one silicon carbon nitride (SiCN) layer formed in the data storage layer, and the at least one SiCN layer isolates the silicon nitride layer into charge trap layers.

18. The semiconductor memory device of claim 17, wherein the carbon containing layer includes silicon oxycarbide (SiOC).

19. The semiconductor memory device of claim 17, wherein the carbon containing layer includes silicon carbide (SiC) and silicon oxynitride (SiON).

20. The semiconductor memory device of claim 17, wherein the carbon containing layer includes carbon nitride (CN) and silicon dioxide (SiO₂).
